(19) United States
(12) Patent Application Publication
(10) Pub. No.: US 2010/0200061 A1
(43) Pub. Date: Aug. 12, 2010

(54) Encapsulated Solar Cell

(75) Inventor: Bernd MELCHIOR, Wermelskirchen (DE)

Correspondence Address: SUMMA, ADDITON & ASHE, P.A., 11610 NORTH COMMUNITY HOUSE ROAD, SUITE 200, CHARLOTTE, NC, 28277, US

(73) Assignee: BLUENERGY AG, Vaduz (LI) (DE)

(21) Appl. No.: 12/766,311

(22) Filed: Apr. 23, 2010

Related U.S. Application Data
(63) Continuation of application No. PCT/EP2008/064086, filed on Oct. 20, 2008.

(30) Foreign Application Priority Data
Oct. 23, 2007 (DE) 102007050964.4
Sep. 5, 2008 (DE) 102008045997.6

(51) Int. Cl. H01L 31/0203; H01L 31/18

(52) U.S. Cl. 136/256; 438/64; 257/E31.117

(57) ABSTRACT

The present invention relates to an encapsulated solar cell having the following layer structure: a lower layer of thermoplastic silicone; a solar cell; an upper layer of thermoplastic silicone; a cover layer of a fluoropolymer, wherein the solar cell is sealed all around between the lower layer and the upper layer and wherein the upper layer is bonded to the cover layer.

### CROSS-REFERENCE TO PRIORITY APPLICATIONS

This application is a continuation of pending International Application No. PCT EP2008/064086 (filed Oct. 20, 2008, and published Apr. 30, 2009, as Publication No. WO 2009/053321 A2,) which itself claims the benefit of commonly assigned German Application Serial No. 10 2008 045 997.6 (filed Sep. 5, 2008), and commonly assigned German Application Serial No. 10 2007 050 964.4 (filed Oct. 23, 2007). This application hereby claims the benefit of and incorporates entirely by reference International Application No. PCT EP2008/064086, German Patent Application Serial No. 10 2008 045 997.6, and German Patent Application Serial No. 10 2007 050 964.4.

### FIELD OF THE INVENTION

The invention relates to an encapsulated solar cell as well as to a method for producing an encapsulated solar cell of this type. Encapsulated solar cells of this type and corresponding methods for the production thereof are generally known, reference is made merely by way of example to EP 0 219 734 A2; U.S. Pat. No. 4,574,160; DE 42 34 068 A1; DE 41 40 682 A1 and PCT/EP94/02942.

### BACKGROUND

The problem with encapsulated solar cells lies among other things in the photochemical effects of sunlight, in particular the UV portion of sunlight, and on the other hand in the surface soiling. It is known that solar cells have to be cleaned from time to time in order to remove the surface soiling. In general, solar cells are erected in a slanting manner outside. If they have a frame, dirt collects on the lower step, i.e. on the lower part of the frame in the transition to the surface of the solar cell. Steps of this type are a disadvantage.

Furthermore, there are other problems with solar cells, for example, the heating up by the infrared portion of sunlight. However, aesthetic issues are also raised, such as the adjustment to the color of the substrate or uniform dying or coloring. The encapsulated solar cell must be completely sealed against environmental effects, for example, the encapsulation materials must not absorb any water or other liquids.

### SUMMARY OF THE INVENTION

On this basis, the object of the invention is to disclose an improved encapsulated solar cell as well as an improved method for the production thereof. This object is attained through the encapsulated solar cell with the following layer structure:

A lower layer of thermoplastic silicon, an upper layer of thermoplastic silicon, and a cover layer of a fluoropolymer, wherein the solar cell is enclosed in a sealed manner on all sides between the lower layer and the upper layer, and wherein the upper layer is bonded to the cover layer.

It is furthermore attained through the method for producing an encapsulated solar cell with the following steps: A lower layer of thermoplastic silicon is applied onto a base, in particular onto a substrate, a solar cell is placed on this lower layer, the lower layer thereby projects on all sides with respect to the solar cell, an upper layer of thermoplastic silicon is placed onto the arrangement, this layer projects on all sides with respect to the solar cell; furthermore, any inclusion of air between the lower layer and the upper layer is avoided, a cover layer of a fluoropolymer is placed on the arrangement, wherein the inclusion of air between the cover layer and the upper layer air is likewise avoided, the arrangement is heated to a temperature until the silicon material is molten, in particular between about 160 to 180°.

The combination according to the invention of a fluoropolymer and of thermoplastic silicon has proven to be extremely successful. Special fluoropolymers are used, which do not turn yellow, which therefore also with ultraviolet radiation exhibit the fewest possible photochemical reactions, preferably no photochemical reactions. In particular, fluoropolymers are suitable, in which an E, if it occurs at all, is not at the beginning in the formula, but in the middle and/or at the end. The yellowing of fluoropolymers, such as, for example, EFEP, which should not be used according to the invention, is attributed to a cleavage of the weak end groups, which cleave acid derivatives under UV light. This leads to a silvering of the solar cells. Any antireflection coating possibly present is also corroded thereby.

Finally, the invention renders possible a refinement of crystal-clear panes, in particular panes of glass, such as are used, for example, as windowpanes. Much smaller film thicknesses can be used hereby than with the encapsulation of solar cells according to the invention, for example, polyene thicknesses that are only ⅕ to 1/10 as thick as with the encapsulation, in particular layers of fluoropolymer with the thicknesses 10 to 20 μm and corresponding layers of thermoplastic silicon with the same thickness.

In principle, the thermoplastic silicon can be applied in any desired form, for example, as a film, it can be sprayed as a lacquer, it can be brushed on, however, it can also be applied in any other layer method, for example, also through the application of grains, which spread out to form a surface under thermal effect.

The invention relates to a combination of silicon films and fluoropolymer films for the encapsulation of solar cells to form modules. Preferably, an edge protection against mechanical and chemical effects as well as atmospheric influences is possible at the same time if at least one film is folded around or wrapped around the edges of the solar cell up to the other main surface of the solar cell.

The encapsulation of the solar cells on a substrate (e.g., glass, metal, plastic, etc.) is carried out via a film combination of a thermal low-melting silicon film (approximately 160 degrees, remelting film around the solar cell) and a high-melting (approx. 300 degrees) fluoropolymer film as an outside cover film.

The silicon film and preferably also the fluoropolymer film located above the solar cells are approximately 10-15 mm larger in terms of area on all sides than the solar cell. The silicon film and preferably also the fluoropolymer film project laterally beyond the solar cell. Furthermore, the silicon film and preferably also the fluoropolymer film is approximately 10-15 mm larger in terms of area on all sides than the substrate. This overhang can be folded around or edged around the substrate such that at least one, preferably both of the films are pulled around the edges and are connected over the area with the bottom of the substrate. An excellent edge protection of the modules is produced hereby, which makes a framing with a solid profile, e.g., an aluminum profile, superfluous.

In the case of a framing with a profile, the profile surrounds the module and a step or an edge is produced on the inside of the module. The draining water accumulates on this edge and the dirt is deposited thereon. An opaque layer of dirt thus forms over the course of time from the lower edge over the solar cell and shades it, which is associated with considerable power losses. The structure according to the invention produces a smooth surface without any accumulation edge for dirt to be deposited. Cleaning is no longer necessary, and a fall-off in power due to dirt streaks can no longer occur. Advantageously, the solar cells can be laminated inside up to the outermost edge of the module. This leads to a reduction in the size of the module or an increase in the module effectiveness.

Strips of silicon films and/or fluoropolymer films around the edges of the substrate (e.g., glass, metal, GRP, wood, etc.) can be used for the mechanical and chemical edge protection of conventional modules. A matching strip of silicon film and fluoropolymer film is drawn around the edges of the module as a mechanical and chemical edge protection. This edge protection is fixedly connected to the module chemically and mechanically by the melting operation such that no water or moisture can penetrate into the module. This is in contrast to a fitted metal frame, which does not have any connection to the module, so that water can penetrate.

Preferably, the fluoropolymer film has a much higher melting point than the silicon film. The laminating temperature is determined by the melting temperature of the silicon film, e.g., 160 degrees; the fluoropolymer film has a melting temperature of, e.g., 300 degrees. All of the temperatures are given in degrees Celsius. The thickness of the high-melting fluoropolymer film is not changed by the laminating operation, so that the same thickness of the fluoropolymer film is always given over all of the elevations of the solar cells as well as with the edging. This is important so that no accidental electric contact (also with high voltage) is possible in the module, not even at thin places. With the edging, a uniform film thickness and thus the edge protection is optimal and remains ensured.

With the edging, the conductor lines can be guided from the top around the edge onto the rear of the module. Due to the constant thickness of the edged fluoropolymer film, no high voltage breakdown occurs. Preferably, the upper fluoropolymer film and the upper silicon film are larger than the module, e.g., approximately 15 mm on all sides. These films are wrapped around the edges of the substrate (e.g., glass, metal, GRP, etc.). The bond to the substrate is permanent and mechanically so strong that framing of the module is not necessary thereby reducing costs. Furthermore, a smooth draining surface is created. No dirt can collect as on aluminum frames. Smooth draining of the rainwater. The solar cells can be laminated inside up to close to the edge, e.g., approximately 2 mm; this makes it possible to reduce the size of the module surface with the same output.

Advantageously, fixing agents or mounting elements are laminated inside as well on the bottom of the edging. The mounting of the modules is carried out on the brackets or on corresponding fixing agents and holders. This produces absolutely flat module surfaces with the bracket, no dirt edges, flow stoppage soiling.

Advantageously, adhesion agents are used for the chemical adhesion of the silicon film to the substrate, e.g., glass. Adhesion agents adapted to the substrate connect the film composite to the substrate permanently. The adhesion agent is preferably incorporated into the silicon film.

Advantageously, the lamination of the combination of silicon and fluoropolymer films is carried out continuously. The silicon film around the solar cell is soft thermoplastic; a continuous encapsulation with enormous cost savings is realized. To this end the silicon film is provided with a rough surface, e.g., a pyramid structure, which prevents the inclusion of air bubbles. During the melting on and compression, the air between the pyramid structures is suctioned off in a vacuum and pressed out mechanically.

Preferably, a type of grid structure is inserted into the surface of the fluoropolymer film, which structure is accordingly optimized according to the refractive index of the fluoropolymer film; this renders possible three important properties and improvements:

Light is absorbed from all angles in the surface and deflected onto the solar cells; this produces a higher yield and is a major advantage for modules that are not optimally aligned to the sun, e.g., in the case of façades, etc.

Through the higher absorption of light, the reflection of the light on the surface is reduced and the modules no longer reflect light depending on the position of the sun. This produces optically appealing, good-looking, attractive modules, e.g., in the case of façades, etc. No distracting glass surfaces and use of the photovoltaics at airports, where reflective surfaces are prohibited.

The grid or dendritic structure has dimensions that lie in the light-wave range, e.g., 400 to 800 nm, and produces as a nanostructure a lotus effect, which, in addition to the good dirt repellence of the fluoropolymer film, results in an additional dirt repellence and self-cleaning. The output of a photovoltaic module depends largely on the transparence of the surface. If the surface is soiled, the output of the module decreases.

Irrespective of the arrangement described above, the dendritic surface structures or grid surface structures can also be used for light absorption from all angles and for producing a lotus effect for better dirt repellence or self-cleaning and anti-reflection of normal commercially available glass panes. As with the encapsulation of the solar cells, the combination of a silicon film and thereon a fluoropolymer film with the grid/dendritic structure can be applied on at least one surface of any commercially available glass pane, and glass panes and windows are produced which never need to be cleaned again. Much thinner films, e.g., 10 to 30 micrometers thick, can be used.

The fluoropolymer film encloses the silicon film preferably hermetically inside, a flowing off or a drifting of the silicon film with the action of heat and load is thereby prevented. The silicon film remains an uncross-linked material and thus can flow through the action of heat. Through the embedding or enclosing with the high-melting fluoropolymer film, a flowing of the silicon film or displacement of the solar cell cannot occur.

Preferably the silicon films and/or fluoropolymer films are subjected to cementary plasma treatment, which leads to an improved adhesion of the composite. The surface of the fluoropolymer film to the silicon film is thereby treated via a physical treatment, e.g., by corona plasma treatment or combinations; this makes fusing with high temperatures superfluous.

Preferably, in the combination of silicon films and fluoropolymer films the contact surface of the fluoropolymer side to the silicon film is vapor-coated with SiO2 and an improved adhesion of the two films is thereby achieved, since the silicon film has a high affinity for SiO2.

Preferably, in the combination of silicon films and fluoropolymer films a mixed polymer film, which is produced from a combination of the granulate of silicon and fluoropolymer, is used as an adhesive intermediate layer. To this end a mixed film is produced from the materials and this then inserted between the fluoropolymer film and the silicon film as an adhesive intermediate layer.

Preferably, in the combination of silicon films and fluoropolymer films a color coordination is carried out. The silicon film under the solar cells is preferably adjusted in terms of color with non-conducting paint pigments to the optical color adjustment to the substrate, e.g., red for use with roof tiles.

Preferably, a color film is contained in the combination of silicon films and fluoropolymer films, in particular laminated inside (e.g., Tedlar black-blue, etc.). The colored substrate is achieved by laminating inside a colored film.

Preferably, in the combination of silicon films and fluoropolymer films the bearing, perforated substrate is inseparably flowed through with the silicon film. In order to incorporate the bearing substrate (e.g., metal plastic plates) permanently into the composite, the substrate is perforated, so that the laminating film can flow through the holes and connect permanently on the rear to the same film.

Preferably, in the combination of silicon films and fluoropolymer films the colored film between the films, in particular silicon films, is perforated so that a permanent bonding of the colored film laminated inside is guaranteed.

Preferably, in the combination of silicon films and fluoropolymer films by folding around the film or films and/or by surrounding at least the one glass pane, a cold flow or hot flow with displacements is prevented. With a modular structure of two glass plates with solar cells lying between them, an edging is carried out as described above.

Through a perforation in the edging region of the substrate, a deep, permanent fusing of the top side and the bottom side along the edge region can be created, no breakdown of the module can occur even with a possible delamination, since the upper melting film and the edged melting film are bonded to one another or fused to one another through the perforation.

Preferably, in the combination of silicon and fluoropolymer films a deep, permanent bond to the substrate is created by means of an adhesion agent. If the affinity of the silicon melting film/embedding film is not sufficient, the adhesion is optimized by corresponding adhesion agents (e.g., silanes, etc.).

Preferably, in the combination of silicon and fluoropolymer films a cold flux and a hot flux are prevented through the insertion of a thermally stable protection (e.g., silicon rubber, fiberglass cloth, etc., in the edge region of approximately 10 mm).

Preferably with a glass/glass composite, the silicon film is roughened on both sides, e.g., structured in a pyramidal manner so that the air can escape on all sides when compressed.

Preferably, amine-free silicon films are used. Through the constant UV exposure in outside use, amine-containing plastics are not free from yellowing. Through the avoidance of amine-containing additives, the silicon film is suitable for use in photovoltaics.

Preferably, adhesion agents are incorporated into the silicon film. In order to avoid the additional step of applying an adhesion agent onto the substrate and solar cell, it is advantageous to incorporate the suitable adhesion agents into the embedding silicon film.

Preferably, one step is omitted due to edging the edges; namely cutting off the overhanging films on the edges of the substrate. With the normal, conventional encapsulation of the solar cells, the laminating films flow out over the substrate edges during heating and compression and have to be cut off and removed in an additional operation. This complex operation is omitted with the edging according to the invention.

Preferably, the substrate is coated beforehand with colored lacquers from the same silicon material. To adapt the substrate in terms of color to the color of the solar cells, the substrate is coated with a colored lacquer of the same silicon material as the silicon laminating film. This produces harmonious esthetic modules.

Preferably, a combination film is produced by means of co-extrusion in a way that the boundary layers of the fluoropolymer film and the silicon film are fused in the extruder such that they become molecularly inseparable.

Preferably, in the combination of silicon and fluoropolymer films both films are bonded with each other inseparably through molecular surface material mixing. A lacquer-like layer made of fluoropolymer and silicon in nanostructure, intensely mixed, is applied in between both films and used as undercoating during thermal lamination such that both films are bonded together inseparably.

Preferably, the fluoropolymer film is made from “material free of weak end groups.” As a result of the UV exposure, acid derivatives are released in the fluoropolymer—loaded with weak end groups—, which causes two negative properties: 1) The fluoropolymer material changes from hydrophobic to hydrophilic, thus absorbing dirt on its surface. 2) In the material these acid derivatives corrode solar cells in such a way that they lose effectiveness resulting in delaminations.

Preferably, the upper fluoropolymer film is equipped with an infrared reflector layer to reflect thermal radiation and to prevent the solar cells from overheating. This results in increased performance of the modules, especially in hot regions of the Sun Belt.

Preferably, both materials in the silicon fluoropolymer film combination are not hygroscopic and absorb neither water nor moisture, so that the solar cells will not corrode. The absorption of water and/or harmful substances is the modules' worst enemy in terms of long-term durability.

Preferably, a fiberglass cloth is inserted above the solar cells, which brings the expansion coefficient in line with the substrate and the film composite. The change from cold to warm and the associated expansions create tension in the solar cells, which can cause delaminations. This can be avoided. Mechanical pressures to the surface are absorbed.

Preferably, the silicon is adjusted such that the mechanical impact is absorbed. Hail can destroy the modules; thus, the embedding material must be adjusted to absorb shocks.

Preferably, in the combination of the fluoropolymer and silicon film for embedding solar cells the surfaces of the fluoropolymer films are adjusted such that the tough-structured surface makes them abrasion-resistant and that sand storms cannot cause any destruction.

Preferably, e.g. pyramid structures, roll laminations (nearly continuous production) can be realized in the combination of fluoropolymer and silicon film for embedding solar cells due to a rough surface with ducts that permit suctioning off air. Normally, photovoltaic modules are produced in vacuum chambers in that the vacuum first suctions off the air between the laminating films and the solar cells, followed by heating and pressing the composite together. This process step is costly and requires a lot of energy. The air can be continuously suctioned off and squeezed out during roll compressing (e.g., roll lamination) through the thermoelastic silicon film with pyramid-like surface structure, so that air pockets are prevented. This makes a more cost-effective production possible.

In one embodiment the substrate is a metal. A fiberglass cloth is placed underneath the solar cells for electrical protection, which is flown through by the silicon film. If the substrate or background is metallic, contact of the current-carrying solar cells with the background must be avoided to prevent shorts and loss of power.

Preferably, in the combination of the fluoropolymer and silicon films the substrate is a perforated sheet metal. For electrical protection a fiberglass cloth is placed underneath the solar cell, which is flown through by the silicon material and causes adhesion on the sheet metal. A silicon film with a covering film, such as for example Tedlar, is also placed behind the perforated sheet. This causes the perforated sheet metal to be flown through by the silicon and an inseparable bond is created.

Preferably, the substrate is a GRP (i.e., fiberglass-reinforced plastic). Preferably, both films, at least however the silicon film, remain thermoplastic in the combination of silicon and fluoropolymer films, and are not cross-linked three-dimensionally. Through appropriate heat exposure this property of the films makes it possible that both materials can be recycled and reused.

Additional properties and advantages of the invention can be inferred from the other claims as well as from the following description of embodiment examples of the invention, which are not meant to be restrictive, and which will be explained below with reference to the accompanying drawings.

### BRIEF DESCRIPTION OF THE DRAWINGS

FIG. 1 shows a partial cross section of an encapsulated solar cell;

FIG. 2 shows a diagram as in FIG. 1, but now with soldering tapes pulled around a lateral edge and a different design of the layer arrangement;

FIG. 3 shows a cross section of a glass pane, a layer made of thermoplastic silicon located on top, and a cover layer of fluoropolymers, and a laminating station; the process of lamination, which can be carried out continuously, is also shown;

FIG. 4 shows a top view of a corner area of a substrate, which is mounted on top of an obliquely cut corner area of a thermoplastic silicon film, to illustrate the film being led around the edges;

FIG. 5 shows the arrangement in accordance with FIG. 4, however the border areas have now been turned to the above-lying rear of the substrate; a sharp corner can be seen;

FIG. 6 shows the arrangement in accordance with FIG. 4, however the folding has now been carefully carried out, the wrapped-around areas are located on the rear of the substrate two-dimensionally; and

FIG. 7 shows the arrangement as in FIG. 6, however now after thermal treatment, the bordering in the area of the diagonal can no longer be seen, the material has joined there, the sharp corner is now rounded off, a bond and an all-around seal has been achieved.

### DETAILED DESCRIPTION

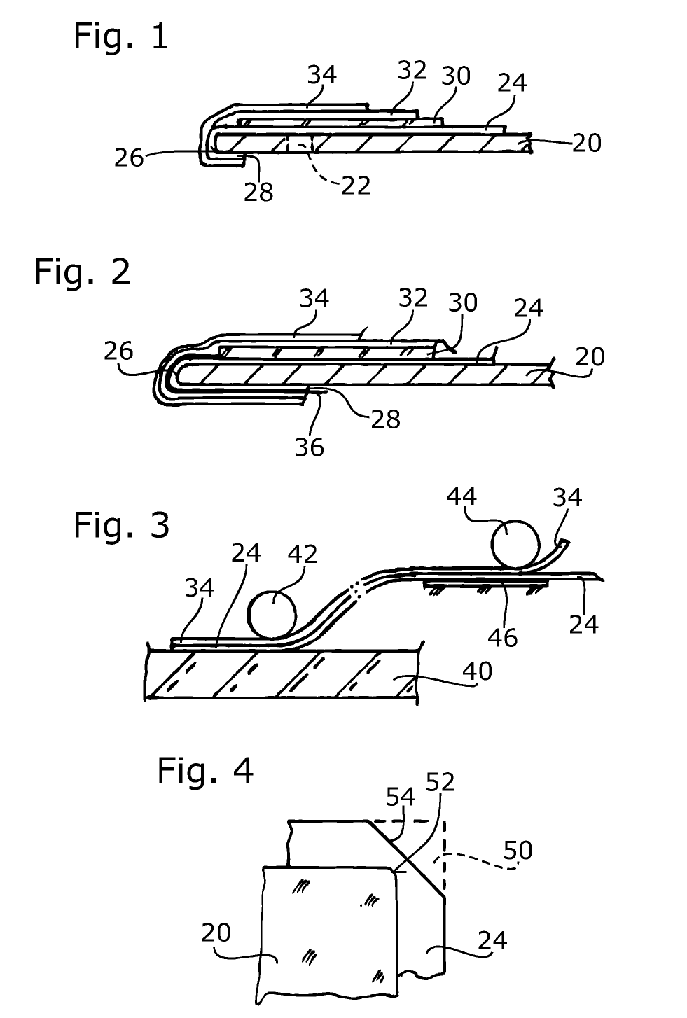

The encapsulated solar cell shown in FIG. 1 has a substrate 20, which is for example an aluminum sheet; it may have openings 22, through which the material of the layers comprised of thermoplastic silicon can flow.

A lower layer 24 comprised of thermoplastic silicon, which is approximately 500 μm thick, is located on the upper main surface of the substrate 20. As shown in FIG. 1, the surface area of this lower layer 24 is larger than the substrate 20. It is wrapped around the edges 26 of the substrate and abuts with its end regions 28 the undersurface of the substrate 20. The contact between the lower layer 24 and the substrate 20 is bubble-free. A bond has been achieved there.

A solar cell 30 is applied to the lower layer 24. This involves a state-of-the-art solar cell. Its surface area can be slightly smaller than the substrate 20, it can, however, virtually also be as large as that of the substrate 20. An upper layer 32 is applied onto this solar cell 30 and to the lower layer 24, unless it is occupied by the solar cell 30. It is made of the same material as the lower layer 24, and also has the same material thickness. If need be, however, it can also be thinner than the lower layer, for example 30% thinner, 50% thinner and even 100% thinner. Its entire surface is also bonded to the solar cell 30, just like the lower layer 24; furthermore, the two layers 24, 32, which are not bonded or fused with one another at the positions that are outside the solar cell 30. Essentially, the purpose of the lines is to be able to actually distinguish the individual layers from each other. In the actual embodiment, namely in the product, virtually no distinctions between the two individual layers 24 and 32, especially 24 and 32, can be detected any longer, if treated thermally, which will be described below.

In the example shown here, the upper layer 32 does not extend around the edges 26 or corners 52 of substrate 20; its surface is essentially identical with the substrate 20.

A cover layer 34 comprised of a fluoropolymer is applied to the upper layer 32. Its thickness ranges from 100-150 μm. Its contact surface with the upper layer 32 is specially treated, for example with plasma or the like, to achieve the tightest possible bond with the material of the two layers 24 and 32. As a cover layer 34, coextruded films may also be used, which at their undersurface show a silicon layer comprised of the silicon material used here.

Through treatment in the range of 160 to 180° C. the entire arrangement was brought to melt and bond in such a way that no air bubbles were enclosed, on the one hand, and a tight composite was created, on the other hand. This was accomplished based on state-of-the-art technology.

Different from the first embodiment example, the surface area of the upper layer 32 according to the embodiment example in FIG. 2 is about the same size as the lower layer 24; thus, the upper layer 32 can also be wrapped around the edges of the substrate 20, as shown. The solar cell 30 has electrical contact strips 36, which run between the two layers 24, 32 and, according to the invention, are wrapped around the edge 26 of the substrate 20, making electrical contacting from the rear of the substrate 20 possible; corresponding contact ends are illustrated.

The embodiment example according to FIG. 3 shows significant steps, which are also suitable to encapsulate solar cells. This applies particularly to continuous roll lamination. A glass pane 40 is shown. A lower layer 24 from the above-described thermoplastic fluoropolymer is applied to one of its main surface areas, possibly even both. Its thickness ranges from 10 to 20 μm. A cover layer 34 comprised of a fluoropolymer, as described hereinabove, is applied to this lower layer 24 and bonded to it. Through thermal treatment in the temperature range as specified the layers are solidly bonded to each other and partially fused. No air bubbles are enclosed.

Roll lamination may be used. A roll 42 is shown, by means of which the lower layer 24 and the upper layer 32, which have already been fused through lamination, are continuously applied to the glass pane 40. This takes place inside a vacuum.

The way the lower layer 24 and the upper layer 32 are jointly led over a table 46, and how they are laminated by a roll 44 there, is also shown. For the lamination process the undersurface of cover layer 34 preferably has a surface wrinkling, which forms continuous ducts, for example a periodic prismatic structure, or the like. This makes it possible for air bubbles to be suctioned out before they even form, thus achieving a tight composite of the layers.

Preferably, in all described embodiment examples at least one of the layers 24, 32 can have such a wrinkling to prevent the enclosure of air bubbles from forming.

The wrapping or edging technology of the films according to the invention will be explained below on the basis of FIGS. 4 to 7.

FIG. 4 shows a substrate 20, which has for example a rectangular shape. However, only an upper right corner area of this substrate 20 is shown. It is placed on a film with a larger surface area of the lower layer 24. Thus, this one, too, has a rectangular cut in the example selected here. However, the corner areas are cut off. Triangles 50 are cut off here; in FIG. 4 such a corner area is shown with a dashed line. Cutting, however, is accomplished in that a distance of several millimeters, for example 2 to 8 mm, remains between the corner 52 of the substrate and the intersecting line 54, as can be seen in FIG. 4.

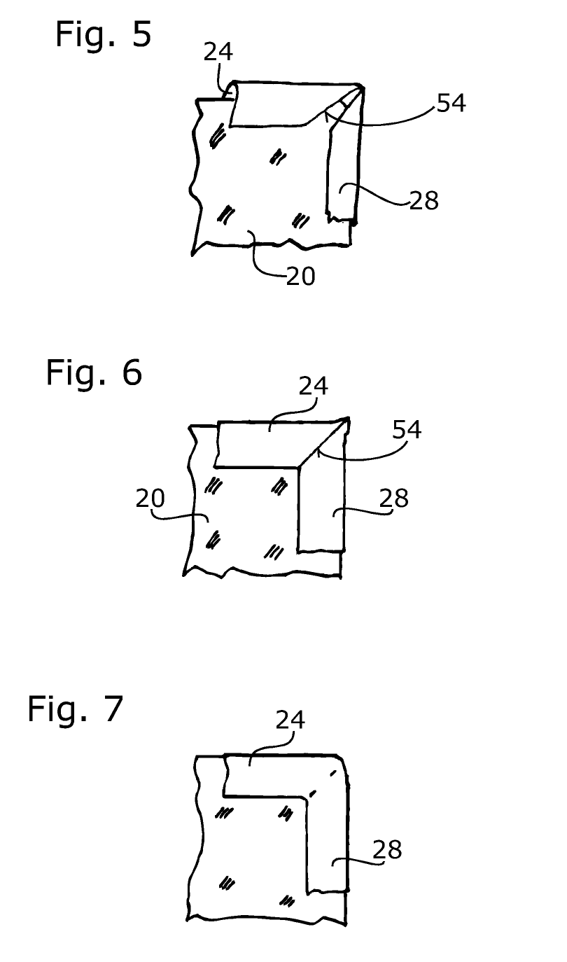

FIG. 5 shows how end regions 28 are wrapped to the rear of the substrate 20. FIG. 5 shows the intermediate state of a folding process. A relatively pointed embodiment of a film edge is shown. Here, it is intended that excess material is available. The opposite edges located on the intersecting line 54 are not yet in contact with one another.

FIG. 6 shows a completely folded state. The two parts of the intersecting line 54 are now in contact. The film corner continues to project.

After thermal treatment—this state is shown in FIG. 7—the material, which only touched before in the area of the intersecting line 54, has now homogenously fused. In the corner area rounding off occurred. The lower layer 24 now abuts the substrate 20 the way it is for example shown in FIG. 1.

It is possible to cover the rear of substrate 20 with a silicon film as well, which is accomplished—based on the state according to FIG. 7—by applying a suitably cut film from the same silicon material that overlaps the surface areas of the end regions and bonds, or fuses with it, through thermal treatment.

The used films or materials show no water absorption. The described embodiment examples can do without metallic frames or any frames at all.

The outer surface of the film of fluoropolymer is provided with a special structure that also shows roughness. A dendritic structure is preferably used. Such structures are produced or used by methods offered by the company Holtronic (www.holtronic.ch). A lotus effect is achieved. The dimensions of the structures range at the nanoscale, especially in the range of visible light, namely 400 to 800 nm. In addition, however, reduced reflection of the surface is achieved.

The fluoropolymer of the encapsulated solar cell 30 is selected from one of MFA, FEP, PFA, AF and similar fluoropolymers. In one embodiment the melting point of the fluoropolymer of the encapsulated solar cell 30 ranges between 275 and 345° C., in particular between 300 and 320° C. Preferably the melting point of the thermoplastic silicon ranges between 50 and 190° C., in particular between 160 and 180° C. In one embodiment the fluoropolymer is a co-polymer. In one embodiment the fluropolymer is described by a chemical formula and an E in the formula of the fluoropolymer—which E stands for ethylene and if the formula contains ethylene at all—is not at the beginning of the formula, but in the middle, such as for example in FEP, or at the end of the formula. In one embodiment the cover layer is made of a film made of fluoropolymer. In one embodiment the cover layer is plasma-treated at least one surface of the cover layer. In one embodiment the film made of fluoropolymer for the cover layer has a material thickness of about 50 to 300 μm, especially 100 to 150 μm, and/or the lower layer and the upper layer each show a material thickness that ranges between 250 μm and 1 mm, especially between 400 μm and 600 μm, especially at 500 μm. The invention also relates to a dirt-repellent, crystal-clear pane, in particular a glass pane covered on at least one main surface with the following layers:

a lower layer of thermoplastic silicon and

a cover layer of a fluoropolymer, wherein the cover layer of a fluoropolymer shows a surface wrinkling in the nanoscale range, in particular a dendritic structure, causing a lotus effect to be generated. Temperatures are in degree Celsius

1. An encapsulated solar cell having a layer structure comprising:
a lower layer of thermoplastic silicon;
a solar cell;
an upper layer of thermoplastic silicon; and
a cover layer of a fluoropolymer;
wherein the solar cell is sealed all around between the lower layer and the upper layer; and
wherein the upper layer is bonded to the cover layer.

2. The encapsulated solar cell in accordance with claim 1, wherein the lower layer and the upper layer are produced from the same material.

3. The encapsulated solar cell in accordance with claim 1, wherein the cover layer is made of a film made of fluoropolymer, at least a portion of the surface of the cover layer treated with plasma.

4. The encapsulated solar cell in accordance with claim 1, the encapsulated solar cell further comprising a substrate in contact with the lower layer;
wherein at least one of the lower layer of thermoplastic silicon, the upper layer of thermoplastic silicon, and the cover layer is wrapped around an edge of the substrate and is bonded in wrapped around regions to the substrate.

5. The encapsulated solar cell in accordance with claim 1, wherein the surface of the cover layer of fluoropolymer adjacent to the upper layer is roughened and laminated in a vacuum without enclosing air bubbles therein.

6. The encapsulated solar cell in accordance with claim 1, wherein the surface of the cover layer shows surface wrinkling in the nanoscale range, a dendritic structure, and a structure provoking a lotus effect.

7. A method for producing an encapsulated solar cell comprising the following steps:
applying a lower layer of thermoplastic silicon onto one of a base and a substrate, the lower layer being above the one of a base and a substrate;
applying a solar cell on top of the lower layer, the lower layer projecting all around the solar cell;
applying an upper layer of thermoplastic silicon onto the solar call, the upper layer projecting all around the solar cell;
removing any enclosure of air between the lower layer and the upper layer;
applying a cover layer of a fluoropolymer to the upper layer;
removing any enclosure of air between the lower layer and the upper layer to obtain a structured arrangement of layers; and
heating the arrangement to a temperature until the silicon material fuses.

8. The method for producing an encapsulated solar cell of claim 7, wherein the lower layer and the upper layer are made from the same material.

9. The method for producing an encapsulated solar cell of claim 7, wherein the surface of film made of fluoropolymer is treated with plasma at a contact surface area with the upper layer.

10. The method for producing an encapsulated solar cell of claim 7, wherein at least one of the lower layer of thermoplastic silicon, the upper layer of thermoplastic silicon, and the cover layer is wrapped around an edge of the substrate and is bonded in a wrapped around region to the substrate.

11. The method for producing an encapsulated solar cell of claim 7, wherein the surface of the cover layer made of fluoropolymer adjacent to the upper layer comprises air ducts; and further comprising the step of laminating the solar cell in a vacuum to avoid the formation of air bubbles within the solar cell.

12. The method for producing an encapsulated solar cell of claim 11, wherein the cover layer made of fluoropolymer is roughened and air ducts are provided by the roughening.
